(19) United States
(12) Patent Application Publication
(10) Pub. No.: US 2009/0325106 A1
(43) Pub. Date: Dec. 31, 2009

(54) Method for Implant Imaging with Spin-on Hard Masks

(76) Inventors: Willard E. Conley, Schenectady, NY (US); Terry G. Sparks, Austin, TX (US); William J. Taylor, JR., Clifton Park, NY (US)

Correspondence Address: HAMILTON & TERRILE, LLP - FREESCALE, P.O. BOX 203518, AUSTIN, TX, 78720, US

(21) Appl. No.: 12/147,889

(22) Filed: Jun. 27, 2008

(51) Int. Cl. H01L 21/02

(52) U.S. Cl. 430/319

(57) ABSTRACT

A semiconductor fabrication method that includes forming a patterned mask (62, 72) by spin coating a developable hard mask layer (32) and a resist layer (42) over a semiconductor substrate (4). Subsequently, the resist layer (42) is exposed and developed to form a patterned resist layer (62), where the development step also removes the underlying hard mask layer (32), thereby forming a patterned mask (62, 72) which defines a void or printed feature to expose a region (97) over the semiconductor substrate which may be implanted, etched or otherwise processed.

### BACKGROUND OF THE INVENTION

1. Field of the Invention

The present invention is directed in general to the field of semiconductor processing. In one aspect, the present invention relates to the manufacture and use of ion implant masks.

2. Description of the Related Art

As a result of innovations in integrated circuit and packaging fabrication processes, dramatic performance improvements and cost reductions have been obtained in the electronics industry. The speed and performance of chips, and hence the computer systems that utilize them, are ultimately dictated by the minimum feature sizes that can be reliably formed using lithographic processes to replicate patterns rapidly from one wafer or substrate to another. A typical lithographic system includes exposure tools, masks, resist, and all of the processing steps required to transfer a pattern from a mask to a resist, and then to devices.

As integrated circuit feature sizes decrease, the ability to selectively implant impurities into an underlying region can be impaired when conventional photoresist implant mask layers are used. For example, the relatively thickness of the gate stack layers increases as device feature sizes are reduced, leading to the requirement of forming higher aspect ratio contacts to make electrical connections to the source/drain regions and gates of the devices. Stated more generally, when forming high aspect ratio contact openings, a thicker layer of photo resist is conventionally used, but the thickness of the photo resist is limited by resolution as well as the etch requirements, as known to one skilled in the art. In addition, the thickness of conventional photoresist layers can impair or block the implantation of impurities into the underlying semiconductor structure. This is illustrated in FIG. 1, which depicts a semiconductor wafer structure 1 which includes a screen oxide layer 312 formed over a substrate layer 310, and a conventional patterned photoresist implant mask layer 314 formed over the screen oxide layer 312. As formed, the photoresist implant mask layer 314 has a thickness 315 (e.g., on the order of at least 300 nm) that is much thicker than the dimension of the implant mask opening 316, and as a result, any implantation of the substrate 310 through the implant mask opening 316 can be blocked or limited by the relatively narrow size of the implant mask opening 316.

Accordingly, a need exists for an improved integration process for forming a semiconductor device which avoids the process and performance limitations associated with thick photoresist implantation masks or with unduly complex fabrication processes. In addition, there is a need for improved mask fabrication processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of a semiconductor wafer structure on which a conventional, patterned photoresist implant mask layer is formed;

FIG. 2 is a partial cross-sectional view of a semiconductor wafer structure having a screen oxide layer formed over a semiconductor substrate in accordance with selected embodiments of the present invention;

FIG. 3 illustrates processing subsequent to FIG. 2 after a spin-on developable hard mask layer is formed;

FIG. 4 illustrates processing subsequent to FIG. 3 after a relatively thin implant photoresist layer is formed;

FIG. 5 illustrates processing subsequent to FIG. 4 after the implant photoresist layer is exposed to an imaging radiation in a first region;

FIG. 6 illustrates processing subsequent to FIG. 5 after submersion in a develop solution removes the implant photoresist layer the first region;

FIG. 7 illustrates processing subsequent to FIG. 6 after submersion in the develop solution removes the exposed developable hard mask layer in the first region;

FIG. 8 illustrates processing subsequent to FIG. 7 in which an implantation of the substrate in the first region is performed using the remaining implant photoresist and developable hard mask layers as an implant mask;

FIG. 9 illustrates processing subsequent to FIG. 8 after the remaining implant photoresist and developable hard mask layers are removed;

FIG. 10 illustrates processing subsequent to FIG. 9 after a spin-on developable hard mask layer is formed;

FIG. 11 illustrates processing subsequent to FIG. 10 after a relatively thin implant photoresist layer is formed;

FIG. 12 illustrates processing subsequent to FIG. 11 after the implant photoresist layer is exposed to an imaging radiation in a second region;

FIG. 13 illustrates processing subsequent to FIG. 12 after submersion in a develop solution removes the implant photoresist layer and the exposed developable hard mask layer the second region;

FIG. 14 illustrates processing subsequent to FIG. 13 in which an implantation of the substrate in the second region is performed using the remaining implant photoresist and developable hard mask layers as an implant mask;

FIG. 15 illustrates processing subsequent to FIG. 14 after the implant mask is removed and gate electrode structures are formed;

FIG. 16 illustrates processing subsequent to FIG. 15 after a spin-on developable hard mask layer and relatively thin implant photoresist layer are formed over gate electrode structures formed in the first and second regions;

FIG. 17 illustrates processing subsequent to FIG. 16 after the implant photoresist layer is exposed to an imaging radiation in the first region;

FIG. 18 illustrates processing subsequent to FIG. 17 after submersion in a develop solution removes the implant photoresist layer and the exposed developable hard mask layer the first region;

FIG. 19 illustrates processing subsequent to FIG. 18 in which an implantation of the source/drain regions in the first region is performed using the remaining implant photoresist and developable hard mask layers as an implant mask; and

FIG. 20 is a flowchart of one embodiment of fabricating a semiconductor device in accordance with the teachings herein.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating an implant mask by using a developable mask layer in combination with a photoresist layer to provide an improvement in process window capability by reducing the overall thickness of the implant mask with a single development step to clear the developable mask and photoresist layers from desired implant areas. For example, a hard mask layer of developable metal-containing organic material (e.g., a titanate bottom anti-reflective coating (BARC) layer or titanate and silicon-containing BARC layer) is applied by deposition or spin-on techniques to cover a semiconductor structure, followed by the deposition of a photoresist layer having a reduced thickness (e.g., from 50 nm to 300 nm). When the photoresist layer is exposed to imaging radiation through a photomask and submersed in a suitable photoresist develop solution, both the exposed photoresist and underlying developable mask layer are removed or cleared from the semiconductor structure to form a patterned implant mask of the remaining portions of the photoresist and underlying developable mask layers. However, the undeveloped portion of the developable mask layer is an etch-resistant and implant-blocking layer that may be used to provide a thinner implant mask. The use of a developable spin-on mask layer allows a thinner photoresist layer to be used, thereby providing improved image and cost advantages over conventional mask techniques which use thicker photoresist layers or more expensive chemical vapor deposition (CVD) processes. Because the disclosed mask layer is developable, the processing of the implant mask formation is simplified since only a single development step is needed. In addition, the developable mask layer simplifies any rework process since the developable mask layer can be easily removed and re-formed with an image and development process that does not damage the underlying semiconductor structure layers. And by including a developable implant etch mask, the implant masks can be optimized to reduce the overall thickness, thereby effectively extending the pattern resolution capabilities so that, for example, high angle or large-angle-tilt ion implantations may be used without blocking or shadowing that would occur with a thicker implant mask layer.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of various semiconductor structure layers without including every feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the implant mask. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

While the implant masks described herein can be fabricated in a variety of different ways, an illustrative example is depicted in the fabrication process flow illustrated beginning with FIG. 2 which illustrates a partial cross-sectional view of a semiconductor wafer structure 2 having a screen oxide layer 22 formed over a semiconductor substrate 20. In particular, the structure 2 includes semiconductor layers 20a, 20b formed on or as part of a semiconductor substrate 20, where the semiconductor layer 20a defines an NMOS area or region 96, while the semiconductor layer 20b defines a PMOS area or region 97. Also illustrated is a shallow trench isolation 21 that divides the layers 20a, 20b into separate regions. Depending on the type of transistor device being fabricated, the semiconductor substrate/layer 20 may be formed from any semiconductor material, including, for example, Si, SiC, SiGe, SiGeC, Ge, GaAs, InAs, InP as well as other III/V or II/VI compound semiconductors or any combination thereof Although a bulk type substrate is shown here for the description of the invention, the invention is not limited to any specific substrate type. For example, the starting substrate for the invention can be of semiconductor-on-insulator (SOI) type having a buried insulator layer under a top layer of semiconductor.

The isolation regions or structures 21 are formed to electrically isolate the NMOS device area(s) 96 from the PMOS device area(s) 97. Isolation structures 21 define lateral boundaries of an active region or transistor region 96, 97 in active layers 20a, 20b, and may be formed using any desired technique, such as selectively etching an opening in the semiconductor substrate/layer 20 using a patterned mask or photoresist layer (not shown), depositing a dielectric layer (e.g., oxide) to fill the opening, and then polishing the deposited dielectric layer until planarized with the remaining semiconductor substrate/layer 20. Any remaining unetched portions of the patterned mask or photoresist layer(s) are stripped.

The screen oxide layer 22 may be formed over the semiconductor substrate/layer 20 and isolation regions or structures 21 by growing or depositing an oxide layer using any desired technique. When the underlying semiconductor substrate/layer 20 is to be implanted, the screen oxide layer 22 serves to protect the underlying semiconductor substrate/layer 20 from processing damage during the implant mask formation.

FIG. 3 illustrates processing of a semiconductor wafer structure 3 subsequent to FIG. 2 after a developable hard mask layer 32 is formed. The developable hard mask layer 32 may be formed from a metal-containing organic material that serves as an bottom anti-reflective coating (BARC) that is used to adequately image the implant openings (as described below). As will be appreciated, a developable material is a material having properties (such as hardness or chemical stability) which can be removed by application of a developer solution or chemistry, such as by spin coating a metal-ion-free develop chemistry (e.g., tetramethylammonium hydroxide (TMAH)), such as provided by the Shipley Company under the name of CD26. The developable hard mask layer 32 may be formed using a metal-containing BARC layer, such as a BARC hard mask layer formed from titanate or a blend of silicon and titanate. Unless developed and removed, the developable hard mask layer 32 provides an implant-blocking function that contributes to the implant resistance of the finally formed implant mask. By forming the hard mask layer 32 with a blend of titanate and silicon (such as provided by Brewer Science under the BSI.S07005 platform), the hard mask layer 32 has resist compatibility and a higher etch resistance as compared to existing photoresist platforms or straight silicon BARC layers. Likewise, titanate BARC hard mask layers (such as provided by Brewer Science under the BSI.D06108 platform) also show resist compatibility. In selected embodiments, the developable hard mask layer 32 is formed as a spin-on BARC layer to a thickness of approximately 30-60 nm, though other thicknesses (e.g., approximately 20-120 nm) and deposition techniques may be used, depending on the particular application.

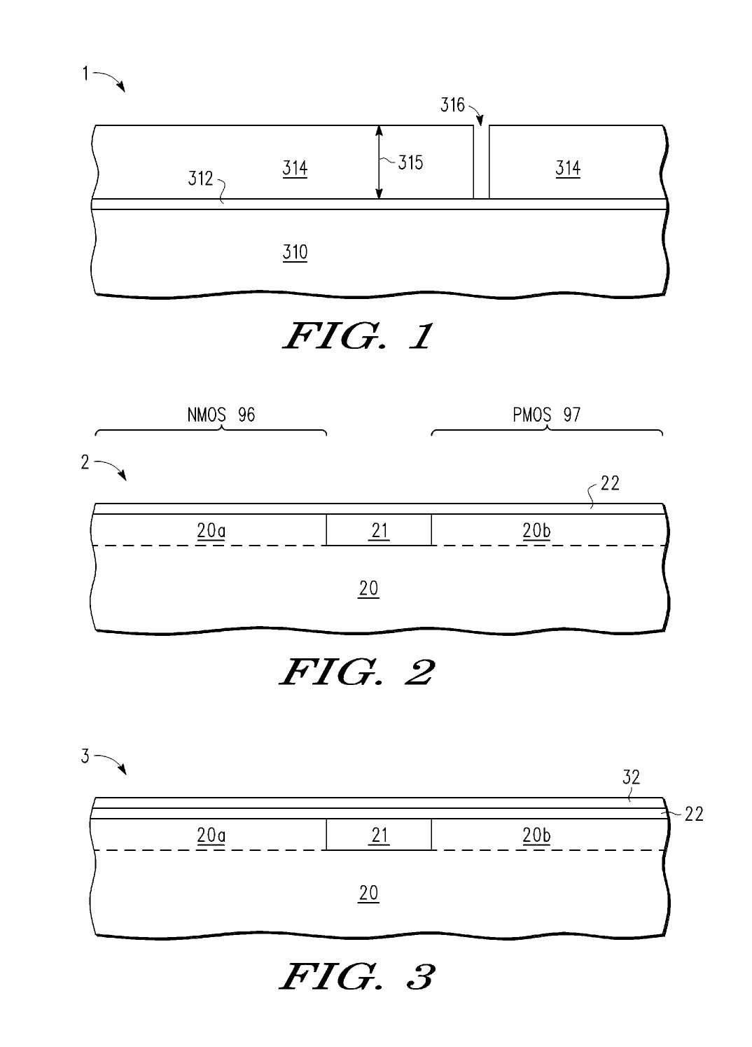

FIG. 4 illustrates processing of a semiconductor wafer structure 4 subsequent to FIG. 3 after a relatively thin implant photoresist layer 42 is formed over the developable hard mask layer 32. The photoresist layer 42 is formed by coating the semiconductor wafer structure 4 with a light-absorbing polymeric material. For example, the photoresist layer 42 may be formed with a suitable lithography resist from Rohm & Haas called UV-60. The photoresist layer 42 may be formed by a spin coating process on the developable hard mask layer 32. However formed, the presence of the underlying developable hard mask layer 32 allows the photoresist layer 42 to be formed to a reduced thickness 43 of approximately 50-300 nm, though other thicknesses may be used, depending on the particular application. After coating the wafer structure with the photoresist layer 42, the photoresist layer 42 is baked at a temperature preferably in the range of 90 to 140° C. to form the photoresist layer 42 shown in FIG. 4. By forming the combined developable hard mask layer 32 and photoresist layer 42 to a thickness that is less than the thickness 315 of the conventional patterned photoresist implant mask layer 314 (such as shown in FIG. 1), the implant blocking or impairment effects that can occur with a conventional thicker photoresist layer are reduced, particularly with large-angle-tilt ion implants. For example, the thinner total mask throws less of a shadow when an angled implant is used, thereby improving the implant accuracy.

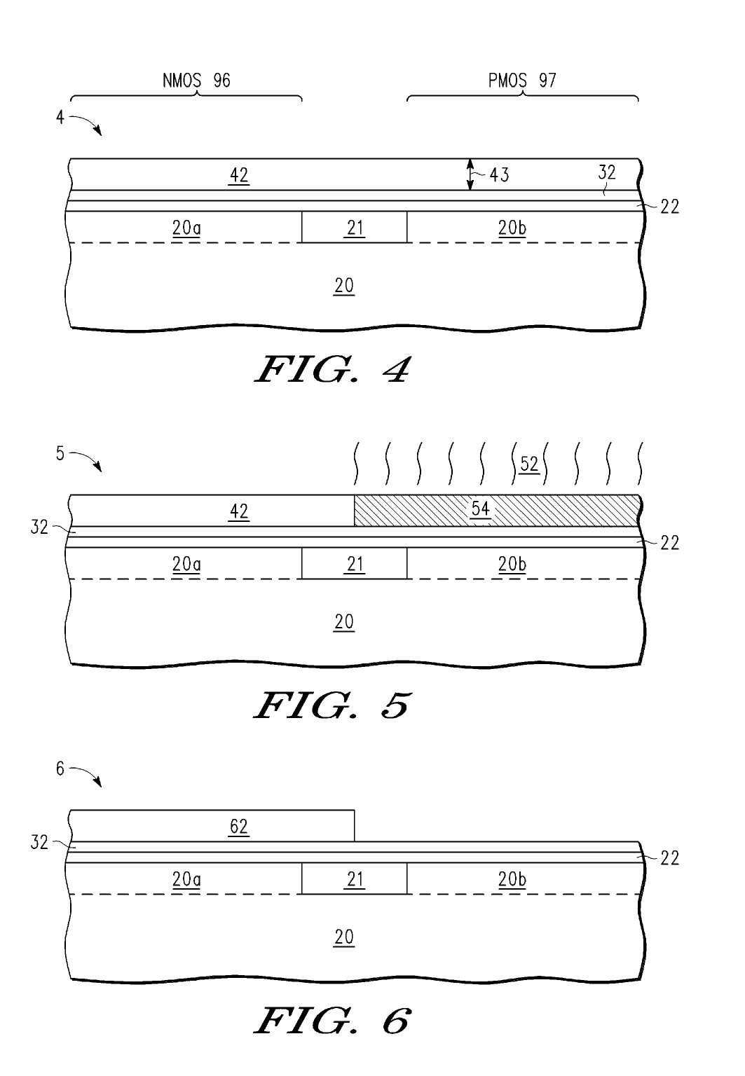

FIG. 5 illustrates processing of a semiconductor wafer structure 5 subsequent to FIG. 4 after the implant photoresist layer 42 is exposed to an imaging radiation 52 through a conventional photomask in a first region 97. The exposure of the photoresist layer 42 may be performed with any desired lithography equipment, including but not limited to, 248 nm or 193 nm lithography equipment. By selectively exposing the photoresist layer 42 to a source of actinic radiation 52, the properties of the radiated photoresist layer 54 are altered so that a development process may be applied to form a patterned photoresist layer 62. In particular, FIG. 6 illustrates processing of a semiconductor wafer structure 6 subsequent to FIG. 5 after submersion in a suitable photoresist develop solution removes the exposed implant photoresist layer 54 the first region 97, thereby creating the patterned photoresist layer 62. To remove the radiated photoresist layer 54, any desired developer solution or chemistry can be applied, such as the metal-ion-free develop chemistry (e.g., TMAH) provided by the Shipley Company under the name of CD26.

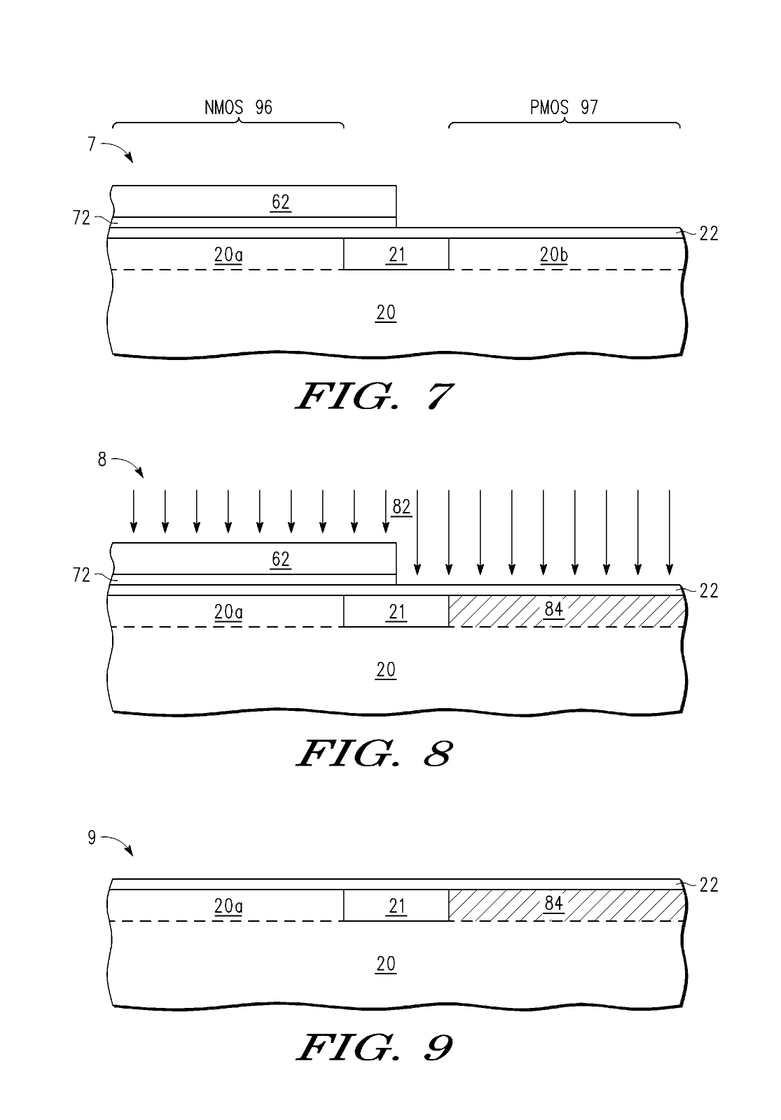

Turning now to FIG. 7, there is illustrated the processing of a semiconductor wafer structure 7 subsequent to FIG. 6 after removal of the radiated photoresist layer 54 and exposed developable hard mask layer 32 in the first region 97. In particular, by continuing to submerge the wafer structure in the photoresist develop solution (e.g., the CD26 develop chemistry) after the radiated photoresist layer 54 is removed, the photoresist develop solution also removes the exposed developable hard mask layer 32 in the first region 97, thereby creating the patterned hard mask layer 72. In this way, the hard mask layer 32 is developed during the development of the photoresist layer 42, thereby eliminating the additional deposition and selective etch steps that would be required if a conventional silicon nitride hard mask layer were used. Thus formed, the patterned photoresist layer 62 and hard mask layer 72 define a void or printed feature in the first region 97. The photolithographic processing of the photoresist layer 42 and hard mask layer 32 to produce the patterned photoresist layer 62 and hard mask layer 72 leaves the underlying semiconductor structure layers (e.g., screen oxide 22) substantially intact since the underlying semiconductor structure layers are not photosensitive.

At this point in the process, if it is determined that the patterned photoresist layer 62 and hard mask layer 72 were not correctly aligned or located on the semiconductor wafer structure, an efficient rework process is allowed since the patterned photoresist layer 62 and hard mask layer 72 can be easily removed and re-formed with an image and development process that does not damage the underlying semiconductor structure layers. For example, the patterned photoresist layer 62 can be removed with a plasma-based ash process, and the patterned hard mask layer 72 can be removed with a gentle strip process, such as an oxide plasma etch and solvent process.

After developing the patterned photoresist layer 62 and hard mask layer 72, ion implantation 82 of an implant substrate region 84 in the first region 97 may be performed using the patterned photoresist layer 62 and hard mask layer 72 as an implant mask, as shown in FIG. 8. For example, to form the n-well regions for the PMOS device area 97, ion implantation of an n-type impurity 82 (e.g., phosphorus) is performed using the patterned photoresist layer 62 and hard mask layer 72 as an implant mask to protect the NMOS device area 96. Having formed the patterned implant mask 62, 72 with a hard mask component layer 72, the patterned implant mask provides blocking power with a reduced overall thickness (e.g., with a thinner resist layer 72). As will be appreciated, the hard mask layer 72 may be formed with a Ti and/or Si BARC hard mask layer having a thickness that is optimized for the particular ion implant species, energy and/or conditions. For example, while FIG. 8 shows that the patterned photoresist layer 62 is used to implant the entire PMOS area 97 with the ion implantation 82 (including part of the shallow trench isolation 21), the patterning process of exposing and developing the mask layers 32, 42 can be used to form much smaller or narrower openings in the mask layers 32, 42, so that a narrow implant mask opening (similar to the implant mask opening 316 shown in FIG. 1) is formed over part of the PMOS semiconductor layer 20b. When forming relatively narrow or small implant mask openings, the inclusion of a hard mask layer 72 allows the overall thickness of the patterned implant mask 62, 72 to be reduced, which can provide implant resolution and accuracy benefits when a high angle implant process is used since the combined implant resistance of the patterned implant mask layers 62, 72 can be selected to provide the required implant resistance for the given species and implant energy used with the high angle implant process. With the reduced thickness, very high angle implant coverage is improved over conventional thick photoresist applications.

After implanting the first region 84, another region on the semiconductor wafer structure may be selectively implanted by forming a second implant mask using the implant mask formation sequence described herein. As an initial step, the patterned photoresist layer 62 and hard mask layer 72 are stripped or removed from the semiconductor wafer structure 9, as shown in FIG. 9. For example, the patterned photoresist layer 62 may be removed with a plasma-based ash process, and the patterned hard mask layer 72 can be removed without damaging the underlying semiconductor structure layers (such as the screen oxide layer 22) by using a gentle strip process, such as an oxide plasma etch and solvent process.

Thereafter, a developable hard mask layer 34 is formed over the semiconductor wafer structure 10 from a metal-containing organic material, as shown in FIG. 10. Again, the developable hard mask layer 32 may be formed by spin coating, depositing or otherwise forming a metal-containing BARC layer (e.g., a layer of titanate or a blend of silicon and titanate) to a thickness of approximately 40-90 nm, though other thicknesses (e.g., approximately 20-120 nm) and deposition techniques may be used, depending on the particular application.

Then, in a process step shown in FIG. 11, a photoresist layer 44 is formed over the semiconductor wafer structure 11 by spin coating and baking a light-absorbing polymeric material on the developable hard mask layer 34. Thus formed, the presence of the underlying developable hard mask layer 34 allows the photoresist layer 44 to be formed to a reduced thickness 45 of approximately 50-300 nm, though other thicknesses may be used, depending on the particular application.

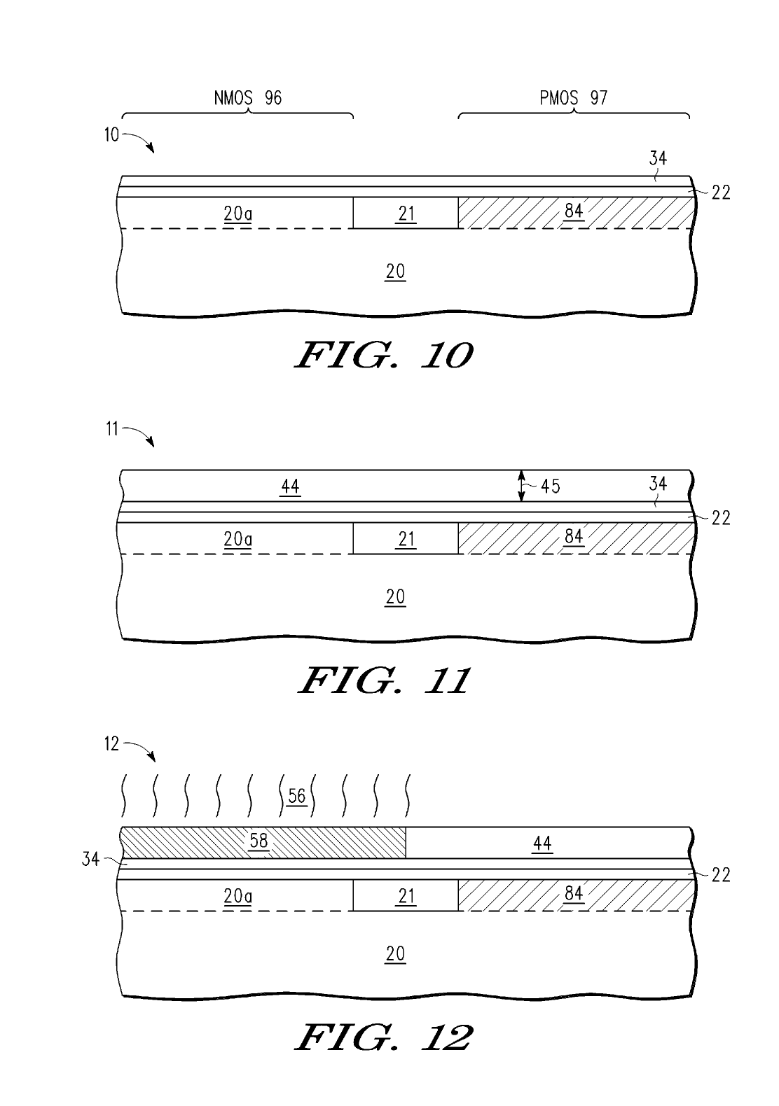

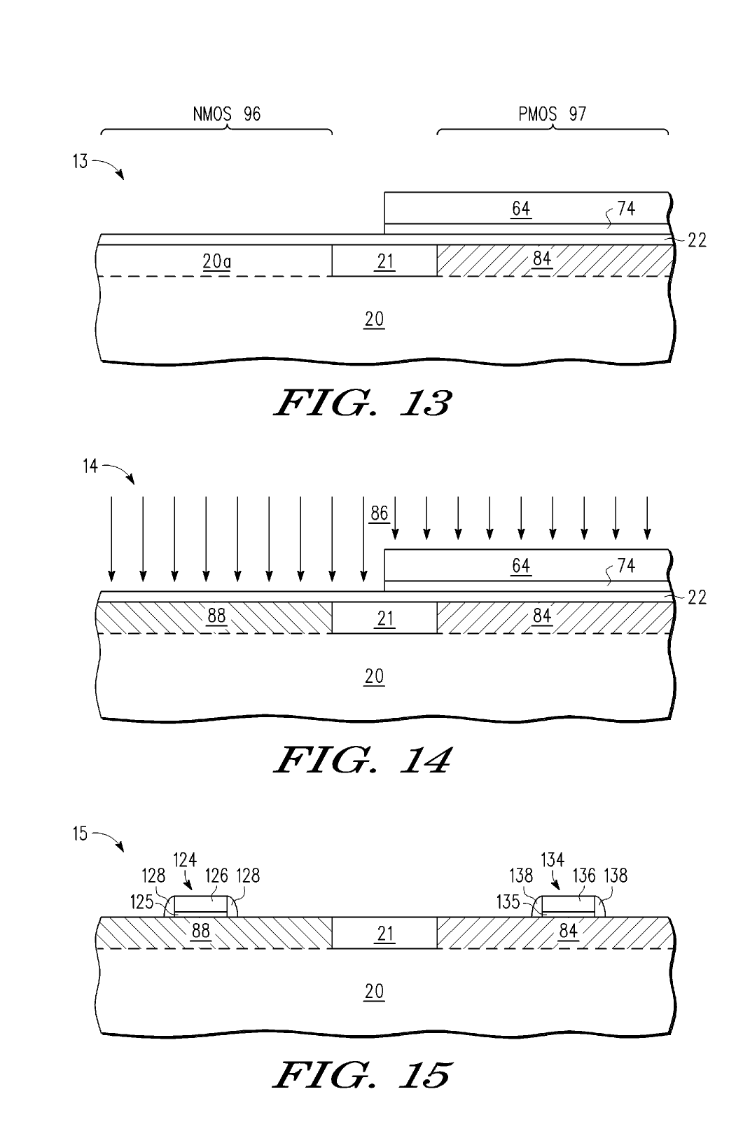

Thereafter, the photoresist layer 44 on the semiconductor wafer structure 12 is aligned and exposed to imaging radiation 56 through a photomask (not shown), thereby altering the properties of the radiated photoresist layer 58, as shown in FIG. 12. By then submersing the semiconductor wafer structure 13 in a suitable photoresist develop solution (e.g., a metal-ion-free develop chemistry such as CD26), both the exposed or radiated photoresist layer 58 and the underlying developable hard mask layer 34 are removed or cleared, resulting in the patterned implant mask shown in FIG. 13. As formed, the patterned implant mask includes the remaining portions of the photoresist layer 64 and underlying developable hard mask layer 74 which together define a void or printed feature in the second region 96. The photolithographic processing of the photoresist layer 44 and hard mask layer 34 to produce the patterned photoresist layer 64 and hard mask layer 74 leaves the underlying semiconductor structure layers (e.g., screen oxide 22) substantially intact since the underlying semiconductor structure layers are not photosensitive.

After developing the patterned photoresist layer 64 and hard mask layer 74, ion implantation 86 of an implant substrate region 88 in the second region 96 is performed using the patterned photoresist layer 64 and hard mask layer 74 as an implant mask, as shown in FIG. 14. For example, to form the p-well regions for the NMOS device area 96, ion implantation of a p-type impurity 86 (e.g., boron) is performed using the patterned photoresist layer 64 and hard mask layer 74 as an implant mask to protect the PMOS device area 97. However, as explained above, the patterning process of exposing and developing the mask layers 34, 44 can be used to form much smaller or narrower openings in the mask layers 34, 44, so that a narrow implant mask opening (similar to the implant mask opening 316 shown in FIG. 1) is formed over part of the NMOS semiconductor layer 20a.

While using a developable hard mask with a photoresist layer may advantageously be used to perform implant imaging in connection with the n-well and p-well implants as described herein, it will be appreciated that the reduced implant mask thickness benefits provided herein may also be used in other parts of the overall fabrication sequence. For example, source/drain implantation processes may also benefit from using a thinner implant mask, particularly where higher aspect ratio contact openings are used to expose the intended source/drain regions and/or gates of the devices. FIGS. 15-18 are cross-sectional views showing process steps for implanting source/drain regions around a previously formed gate electrode with sidewall spacers, though it will be appreciated, that the patterning process of exposing and developing the developable mask and photoresist layers can be used to form much smaller or narrower implant openings so that smaller source/drain implant regions may be formed in the substrate.

Starting with FIG. 15, there is illustrated processing of a semiconductor wafer structure 15 subsequent to FIG. 14 after the patterned photoresist layer 64 and hard mask layer 74 are removed, and NMOS and PMOS gate electrode structures(s) 124, 134 are formed in the NMOS and PMOS areas 96, 97, respectively. As illustrated, NMOS gate electrode structure includes one or more gate dielectric layers 125, a conductive gate electrode 126 overlying the gate dielectric 125, and sidewall spacers 128 formed from one or more dielectric layers on the sidewalls of gate electrode 126, all formed over the p-type active area 88. In similar fashion, PMOS gate electrode structure 134 includes one or more gate dielectric layers 135, a conductive gate electrode 136 overlying the gate dielectric 135, and sidewall spacers 138 formed from one or more dielectric layers on the sidewalls of gate electrode 136, all formed over the n-type active area 84. Gate dielectric layer(s) 125, 135 may be formed by depositing or growing an insulator or high-k dielectric (e.g., silicon dioxide, oxynitride, metal-oxide, nitride, etc.) over the NMOS substrate layer 88 and PMOS substrate layer 84 using chemical vapor deposition (CVD), plasma-enhanced chemical vapor deposition (PECVD), physical vapor deposition (PVD), atomic layer deposition (ALD), thermal oxidation, or any combination(s) of the above to a predetermined final thickness in the range of 0.1-10 nanometers, though other thicknesses may be used. Conductive gate electrodes 126, 136 may be a heavily doped (n+) polysilicon gate electrode, a metal gate electrode, or a combination thereof that is formed using any desired deposition or sputtering process, such as CVD, PECVD, PVD, ALD, molecular beam deposition (MBD) or any combination(s) thereof to a predetermined final thickness in the range of 1-100 nanometers, though other thicknesses may be used. Sidewall spacers 128, 138 may be formed from an offset or spacer liner layer (e.g., a deposited or grown silicon oxide), alone or in combination with an extension spacer formed by depositing and anisotropically etching a layer of dielectric. Subsequent to forming at least the gate electrodes 126, 136, lightly doped extension regions (not shown) may be formed by selectively masking the NMOS areas 96 and PMOS areas 97 implanting the appropriate impurities into the exposed substrate layers 84, 88 using the gate electrode(s) 126, 136, alone or with an offset/spacer liner layer, as an implant mask.

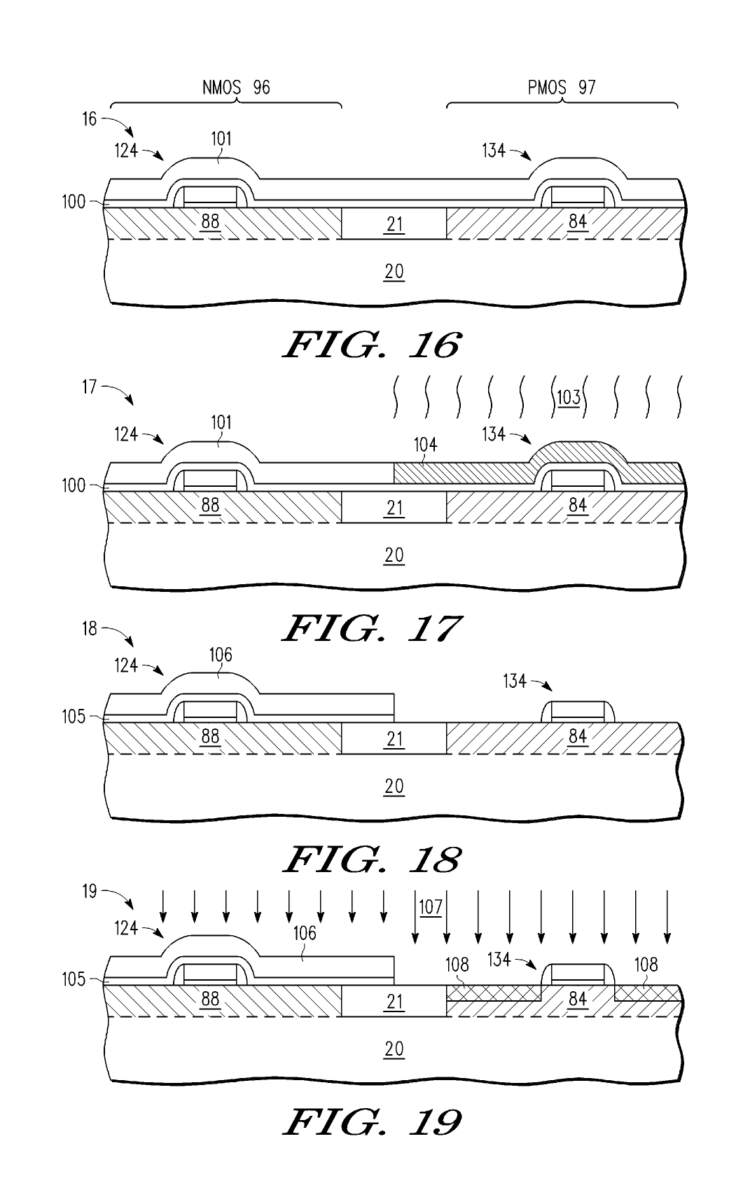

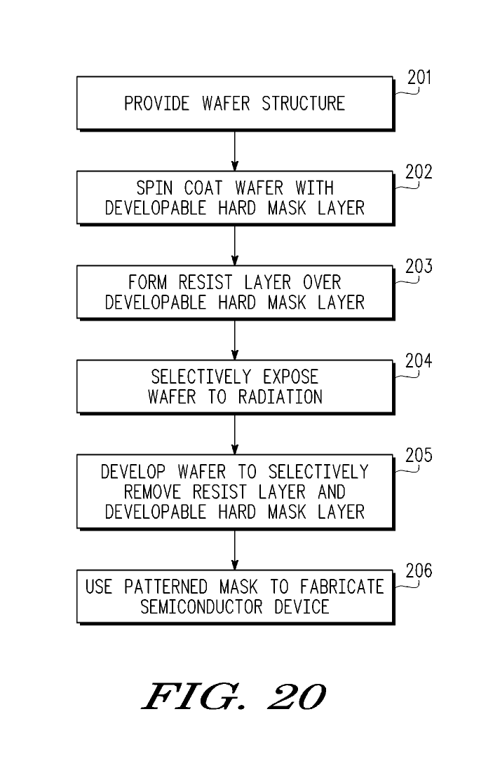

Turning now to FIG. 16, there is illustrated processing of a semiconductor wafer structure 16 subsequent to FIG. 15 after a developable hard mask layer 100 and relatively thin implant photoresist layer 101 are formed over the gate electrode structures 124, 134 formed in the first and second regions 96, 97. As described herein, the developable hard mask layer 100 may be formed by spin coating a developable organic, metal-containing material (e.g., a titanate bottom anti-reflective coating (BARC) layer or titanate and silicon BARC layer) on the semiconductor wafer structure 16, followed by forming the photoresist layer 101 with a spin coating process on the developable hard mask layer 100. Subsequently, alignment is performed on the resist layer 101, and the PMOS region 97 (in this example) is selectively exposed to an imaging radiation 103 (as shown in FIG. 17) to form a radiated photoresist layer 104 in the first region 97. Thereafter, a suitable photoresist develop solution is applied to selectively remove portions of the developable hard mask layer 100 and implant photoresist layer 101 in the first region 97, thereby creating a patterned implant mask from the remaining hard mask layer 105 and implant photoresist layer 106 as shown in FIG. 18. In particular, by submerging the semiconductor wafer structure 17 in a develop solution after the radiated photoresist layer 104 is removed, the photoresist develop solution also removes the exposed developable hard mask layer 100 in the first region 97, thereby creating the patterned hard mask layer 105. By developing the hard mask layer 100 during the development of the photoresist layer 101, additional deposition and selective etch steps may be avoided that would otherwise be needed to form a conventional silicon nitride hard mask layer. With the patterned implant mask 105, 106 in place, an ion implantation 107 of the source/drain regions 108 in the PMOS region 97 is performed, as shown in FIG. 19. For example, to form the p-type source/drain regions 108 for the PMOS device area 97, ion implantation of a p-type impurity 107 (e.g., boron) is performed using the patterned photoresist layer 106 and hard mask layer 105 as an implant mask to protect the NMOS area or region 96. As will be appreciated, the NMOS source/drain regions may also be formed using a similar sequence for selectively forming a patterned implant mask from a developable hard mask layer and a thin photoresist layer over the PMOS area or region 97.

The use of a developable implant mask described herein in making a semiconductor device may be understood with reference to the flowchart depicted in FIG. 20. As shown therein, such a method will typically involve providing wafer structure in step 201. A spin coat process may then be applied to coat the wafer with an organic, metal-containing developable hard mask layer in step 202, followed by the formation of a resist layer over the developable hard mask layer in step 203. Subsequently, a suitable source of actinic radiation is selectively applied (e.g., through a photomask) as shown in step 204. As shown in step 205, the resist layer and developable hard mask layer are then developed into a patterned mask by submersing the wafer in a suitable photoresist develop solution. The patterned mask may then be used to perform any desired semiconductor process, such as an implantation or polysilicon etch process, in the course of fabricating one or more circuit features in a semiconductor wafer structure or device, as shown in step 206.

By now it should be appreciated that there is provided herein a fabrication process for making a semiconductor device. As disclosed, a semiconductor wafer structure is provided that may include an oxide layer or other previously-formed circuit features (e.g., gate electrode structures). Over the semiconductor wafer structure, a developable hard mask layer is formed from a metal-containing organic material. In selected embodiments, the developable hard mask layer is formed by spin coating a titanate-based layer (e.g., a layer of titanate or a blend of titanate and silicon) on the semiconductor wafer structure to a predetermined thickness (e.g., approximately 40 to 90 nanometers). Subsequently, a resist layer is formed over the developable hard mask layer to a predetermined thickness (e.g., approximately 100 to 300 nanometers). After aligning the resist layer, it is selectively exposed to a source of actinic radiation. When the resist layer is developed to selectively remove one or more portions of the resist layer, the development process also removes one or more portions of the developable hard mask layer, thereby forming a patterned mask from any remaining portions of the resist layer and the developable hard mask layer. The patterned mask may be used as an implant mask to implant impurities into the semiconductor wafer structure, or may be used as an etch mask to form one or more circuit features by selectively etching the semiconductor wafer structure. If there is a need to rework the patterned mask, any remaining portions of the resist layer may be removed after developing the resist layer (e.g., with an ash process), and any remaining portions of the developable hard mask layer may be developed or stripped from the semiconductor wafer structure. At this point, the semiconductor wafer structure is cleared, so a second developable hard mask layer may be formed over the semiconductor wafer structure, and a second resist layer may be formed over the second developable hard mask layer. By selectively exposing the second resist layer to a source of actinic radiation, and then developing the second resist layer to selectively remove portions of the second resist layer, the underlying portions of the second developable hard mask layer are also removed, thereby forming a second patterned mask from any remaining portions of the second resist layer and the second developable hard mask layer.

In another form, there is provided semiconductor fabrication method and resulting apparatus. As disclosed, an insulating layer is formed over a semiconductor substrate in at least a first region. Subsequently, a metal-containing, implant resistant developable mask layer is formed on the insulating layer, such as by spin coating a titanium-containing layer on the insulating layer to a predetermined thickness (e.g, to a thickness of approximately 40 to 90 nanometers). On the developable mask layer, a resist layer is formed, such as by depositing a layer of photoresist to a predetermined thickness (e.g., approximately 50 to 300 nanometers). Thus formed, the combined thickness of the developable mask layer and resist layer may be optimized to a predetermined thickness (e.g., less than 300 nanometers) that provides implant resistance for a particular set of ion implant conditions used in the subsequent implanting step. Once the developable mask layer and resist layer are formed, they may be selectively developed (e.g., by selectively exposing the resist layer to a source of radiation and then developing the layers with a development solution) to remove one or more portions of the resist layer along with one or more underlying portions of the developable mask layer while leaving the insulating layer substantially in place, thereby forming a patterned mask from any remaining portions of the resist layer and the developable mask layer. Thereafter, the semiconductor substrate may be implanted using the patterned mask as a mask for ion implantation. For example, the ion implantation may be performed using a large-angle-tilt ion implantation process which uses the patterned mask as a mask for ion implantation.

In yet another form, there is provided method for fabricating a semiconductor device. In the disclosed methodology, an insulating film is formed over at least part of a wafer structure, a developable hard mask layer is formed on an insulating film that includes an organic, metal-containing material, and a resist layer is formed on the developable hard mask layer. In selected embodiments, the developable hard mask layer is formed by spin coating a titanium-containing layer on the insulating layer, and the resist layer is formed such that the developable hard mask layer and resist layer are formed to a combined thickness of less than 300 nanometers. After the resist layer is formed, it is selectively exposed to a source of imaging radiation, and then developed to selectively remove one or more portions of the resist layer along with one or more portions of the developable hard mask layer while leaving the insulating film substantially in place, thereby forming a patterned mask from any remaining portions of the resist layer and the developable hard mask layer. With the patterned mask in place, the wafer structure may be implanted with ion impurities using the patterned mask as an ion implantation mask. In selected embodiments, the patterned mask may be reworked prior to implanting impurities into the wafer structure by removing the remaining portions of the resist layer and the developable hard mask layer while leaving the insulating film substantially in place, forming a second developable hard mask layer over the insulating film, forming a second resist layer over the second developable hard mask layer, and selectively developing the second resist layer and the second developable hard mask layer to form a second patterned mask from any remaining portions of the second resist layer and the second developable hard mask layer.

Although the described exemplary embodiments disclosed herein are directed to various developable photolithography masks and methods for making same, the present invention is not necessarily limited to the example embodiments which illustrate inventive aspects of the present invention that are applicable to a wide variety of mask fabrication processes and/or structures. Thus, the particular embodiments disclosed above are illustrative only and should not be taken as limitations upon the present invention, as the invention may be modified and practiced in different but equivalent manners apparent to those skilled in the art having the benefit of the teachings herein. For example, while a selected embodiment employs a layer of titanate as a developable mask layer, it will be appreciated that the particular material used, and the thickness of that material, may vary from one application to another. In addition, it will be appreciated that the teachings herein are not limited to a specific wavelength of actinic radiation. And while described herein with reference selected implant mask embodiments, it will be appreciated that the patterned mask formed with a developable hard mask and resist layers may also be used as an etch mask for selectively etching an underlying layer, such as a polysilicon, dielectric or other material layer. Moreover, the thickness of the described layers may deviate from the disclosed thickness values. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a semiconductor device, comprising:
providing a semiconductor wafer structure;
forming a developable mask layer over the semiconductor wafer structure comprising a metal-containing material;
forming a resist layer over the developable mask layer;
selectively exposing the resist layer to a source of radiation; and
applying a develop solution to selectively remove one or more portions of the resist layer along with one or more underlying portions of the developable mask layer, thereby forming a patterned mask from any remaining portions of the resist layer and the developable mask layer.

2. The method of claim 1, where forming the developable mask layer comprises spin coating the developable mask layer on the semiconductor wafer structure.

3. The method of claim 1, where forming the developable mask layer comprises forming a titanate-containing layer on the semiconductor wafer structure.

4. The method of claim 1, where forming the developable mask layer comprises spin coating a titanate-containing layer on the semiconductor wafer structure.

5. The method of claim 1, where forming the developable mask layer comprises forming the developable mask layer to a predetermined thickness of approximately 40 to 90 nanometers.

6. The method of claim 1, where forming the developable mask layer comprises spin coating a layer comprising a blend of titanate and silicon.

7. The method of claim 1, where forming the resist layer comprises depositing a resist layer to a predetermined thickness of approximately 50 to 300 nanometers.

8. The method of claim 1, further comprising:
removing any remaining portions of the resist layer after developing the resist layer;
developing any remaining portions of the developable mask layer to remove the remaining portions of the developable mask layer from the semiconductor wafer structure;
forming a second developable mask layer over the semiconductor wafer structure;
forming a second resist layer over the second developable mask layer;
selectively exposing the second resist layer to a source of radiation; and
developing the second resist layer to selectively remove one or more portions of the second resist layer along with one or more portions of the second developable mask layer, thereby forming a second patterned mask from any remaining portions of the second resist layer and the second developable mask layer.

9. A semiconductor fabrication method, comprising:
forming an insulating layer over a semiconductor substrate;
forming a metal-containing, implant resistant developable mask layer on the insulating layer;
forming a resist layer on the developable mask layer;
selectively developing the resist layer and the developable mask layer to remove one or more portions of the resist layer along with one or more underlying portions of the developable mask layer while leaving the insulating layer substantially in place, thereby forming a patterned mask from any remaining portions of the resist layer and the developable mask layer; and
implanting the semiconductor substrate using the patterned mask as an implant mask.

10. The method of claim 9, where forming the metal-containing, implant resistant developable mask layer comprises spin coating a titanium-containing layer on the insulating layer.

11. The method of claim 9, where forming a metal-containing, implant resistant developable mask layer comprises spin coating a layer comprising a blend of titanate and silicon.

12. The method of claim 9, where forming the metal-containing, implant resistant developable mask layer comprises spin coating a titanium-containing layer to a predetermined thickness of approximately 40 to 90 nanometers.

13. The method of claim 9, where the metal-containing, implant resistant developable mask layer and resist layer are formed to a combined thickness of less than 300 nanometers.

14. The method of claim 9, where forming the resist layer comprises depositing a resist layer to a predetermined thickness of approximately 50 to 300 nanometers.

15. The method of claim 9, where implanting the semiconductor substrate comprises implanting impurities into the semiconductor substrate using a large-angle-tilt ion implantation process which uses the patterned mask as an implant mask.

16. The method of claim 9, where the metal-containing, implant resistant developable mask layer and resist layer are formed to a combined thickness that is optimized to provide implant resistance for a particular set of ion implant conditions used in the implanting step.

17. The method of claim 9, where selectively developing the resist layer and the developable mask layer comprises:
selectively exposing the resist layer to a source of radiation; and
developing the resist layer to selectively remove one or more portions of the resist layer along with one or more portions of the underlying developable mask layer while leaving the insulating layer substantially in place, thereby forming a patterned mask from any remaining portions of the resist layer and the developable mask layer.

18. A method for fabricating a semiconductor device, comprising:
a) forming an insulating film over at least part of a wafer structure;
b) forming a developable hard mask layer on an insulating film, where the developable hard mask layer comprises an organic, metal-containing material;
c) forming a resist layer on the developable hard mask layer;
d) selectively exposing the resist layer to a source of imaging radiation;
e) developing the resist layer to selectively remove one or more portions of the resist layer along with one or more portions of the developable hard mask layer while leaving the insulating film substantially in place, thereby forming a patterned mask from any remaining portions of the resist layer and the developable hard mask layer; and
f) implanting impurities into the wafer structure using the patterned mask as an implant mask.

19. The method of claim 18, where forming the developable hard mask layer comprises spin coating a titanium-containing layer on the insulating layer, and where forming the resist layer comprises depositing a resist layer so that the developable hard mask layer and resist layer are formed to a combined thickness of less than 300 nanometers.

20. The method of claim 18, further comprising reworking the patterned mask prior to implanting impurities into the wafer structure by removing the remaining portions of the resist layer and the developable hard mask layer while leaving the insulating film substantially in place, forming a second developable hard mask layer over the insulating film, forming a second resist layer over the second developable hard mask layer, and selectively developing the second resist layer and the second developable hard mask layer to form a second patterned mask from any remaining portions of the second resist layer and the second developable hard mask layer.
